(19) United States
(12) Patent Application Publication
(10) Pub. No.: US 2017/0158563 A1
(43) Pub. Date: Jun. 8, 2017

(54) Material for a Thermoelectric Element and Method for Producing a Material for a Thermoelectric Element

(71) Applicant: EPCOS AG, Muenchen (DE)

(72) Inventors: Hermann Gruenbichler, St. Josef (AT); Yongli Wang, Frauental (AT); Manfred Schweinzger, Schwanberg (AT)

(21) Appl. No.: 15/327,012

(22) PCT Filed: Jul. 7, 2015
(86) PCT No.: PCT/EP2015/065470

§ 371 Date: Jan. 17, 2017

(30) Foreign Application Priority Data
Jul. 17, 2014 (DE) 10 2014 110 065.4

(51) Int. Cl. C04B 35/01; H01L 35/22; H01L 35/34; C04B 35/64

(52) U.S. Cl. CPC C04B 35/016; C04B 35/64; H01L 35/22; H01L 35/34; C04B 2235/3208; C04B 2235/3201; C04B 2235/3213; C04B 2235/3224; C04B 2235/3268; C04B 2235/3274; C04B 2235/3275; C04B 2235/656; C04B 2235/6567; C04B 2235/6565; C04B 2235/768; C04B 2235/79; C04B 2235/9607

(57) ABSTRACT

A material for a thermoelectric element and a method for producing a material for a thermoelectric element are disclosed. In an embodiment the thermoelectric element includes a material comprising calcium manganese oxide that is partially doped with Fe atoms in positions of Mn atoms.

This patent application is a national phase filing under section 371 of PCT/EP2015/065470, filed Jul. 7, 2015, which claims the priority of German patent application 10 2014 110 065.4, filed Jul. 17, 2014, each of which is incorporated herein by reference in its entirety.

### TECHNICAL FIELD

A material for a thermoelectric element and a method for producing a material for a thermoelectric element are provided. For example, the material is an electron conductor based on a complex metal oxide, particularly a ceramic.

### BACKGROUND

The increase in global energy consumption is causing increased production of waste heat, which is often not used at all or used only to an insufficient extent. For example, even in modern combustion engines in automobiles, a large portion of the energy is lost via the exhaust as waste heat. Thermoelectric conversion offers an attractive possibility for increasing general efficiency in energy production and can play a role in reducing CO₂ production. Use of a thermoelectric element does not require any moving parts, which are subject to wear. Moreover, there is no accumulation of waste products such as carbon dioxide that have adverse climatic effects.

The dimensionless figure of merit, ZT, can be used to describe the thermoelectric efficiency of a material. This value is derived from the following equation:

$$ZT = \frac{( {σα}^{2} ) T}{κ} \qquad ( 1 )$$

where σ denotes electrical conductivity, α the Seebeck coefficient (“thermopower”), T temperature, and κ thermal conductivity.

The publication DE 11 2008 002 499 T5 discloses a method for producing a complex metal oxide that can be used as a thermoelectric conversion material.

### SUMMARY OF THE INVENTION

Embodiments of the invention provide an improved material for a thermoelectric element and an improved method for producing a material for a thermoelectric element.

According to a first aspect of the present invention, a material for a thermoelectric element is provided. The material comprises calcium manganese oxide, preferably of the general formula CaMnO₃. The calcium manganese oxide is partially doped with Fe atoms in the positions of Mn atoms.

The material is preferably in the form of a perovskite crystal structure represented by the general formula ABO₃, where A denotes the A positions and B the B positions of the perovskite lattice. The A positions are primarily occupied with Ca²⁺ atoms, and the B positions are primarily occupied by Mn⁴⁺ atoms. In doping with Fe atoms, portions of the B positions are occupied by Fe⁴⁺ atoms. This corresponds to “isovalent” doping without a donor effect.

It has been found that the thermopower of the material can be improved by doping with iron. According to equation (1), therefore, the figure of merit of the material can be increased. In addition, a reduction in the thermal conductivity of the material is to be expected in doping with iron, which contributes toward further improvement of the figure of merit.

In an embodiment, doping with Fe atoms is provided with a content z, where z≦20%. This means that up to 20% of the Mn positions in the lattice, in particular the B positions in the perovskite lattice, are occupied by Fe⁴⁺ atoms. In particular, the amount can be in the range of 0.01% to 20%. In an embodiment, z≦5%, and in particular, 0.01%≦z<5% is true.

The material is preferably of the “n-type”. In an “n-type” material, electrons are present as charge carriers. In a “p-type” material, holes are present as charge carriers.

In an embodiment, Ca atoms in the material are partially replaced by other atoms in order to further improve the properties of the material. In particular, doping is provided in the A position of the Perovskite lattice.

In an embodiment, the material is partially doped with an element that replaces Ca²⁺ in the crystal lattice and provides electrons for electrical conductivity. This makes it possible to increase the number of charge carriers. For example, the element is selected from a group consisting of the rare earth metals, Sb³⁺, and Bi³⁺. The group is preferably composed of Y³⁺, Sc³⁺, La³⁺, Nd³⁺, Gd³⁺, Dy³⁺, Yb³⁺, Ce⁴⁺, Sb³⁺ and Bi³⁺.

For example, doping with the element that can replace Ca²⁺ in the crystal lattice and provides electrons for electrical conductivity can be provided with a content y, where 0%<y≦50%. This means that up to 50% of the positions of Ca atoms are occupied by this element. y is preferably ≧1%. y is preferably ≦10%.

In an embodiment, the material is partially doped with a divalent element in the positions of Ca²⁺ atoms. This therefore constitutes isovalent doping. For example, the divalent element is selected from a group consisting of Mg²⁺, Sr²⁺, Ba²⁺, Zn²⁺, Pb²⁺, Cd²⁺, and Hg²⁺. Sr²⁺ is preferably used.

For example, doping with the divalent element is provided with a content x, where 0%<x≦50% of the positions of the Ca atoms is true. x is preferably ≧5%. x is preferably ≦20%.

In an embodiment, calcium manganese oxide is represented by the general formula CaMnOₙ, where n denotes the formula units of oxygen. In particular, n≧2 is true. Preferably, n˜3 or n=3 is true. The manganese contained in the compound can have different valencies. In particular, it is possible for a portion of the manganese to be reduced from Mn⁴⁺ to Mn³⁺. In order to ensure charge neutrality within the compound, some oxygen may be removed so that n is formally less than 3.

In an embodiment, the material is represented by the following general formula:

Ca_{1-x-y}ISOₓDON_{y}Mn_{1-z}Fe_{z}Oₙ

where

Ca is the chemical symbol for calcium,

ISO is a divalent element that can replace Ca²⁺ in the crystal lattice,

DON is an element that can replace Ca²⁺ in the crystal lattice and provides electrons for electrical conductivity,

Mn is the chemical symbol for manganese,

Fe is the chemical symbol for iron, and

O is the chemical symbol for oxygen,

where x, y, and z denote the contents of the respective elements and n denotes the formula units of oxygen.

For example, x, y, z, and n can be selected as described above.

In an embodiment, x, y, z, and n are in the following ranges:

Content of ISO: 0≦x≦0.5, and particularly 0.05≦x≦0.20

Content of DON: 0≦y≦0.5, and particularly 0.01<y≦0.10

Content of Fe: 0.0001≦z<0.2

Formula units of oxygen: n≧2, and particularly n˜3.

The material preferably contains few or no elements that are costly or toxic. In particular, the material is free of selenium and tellurium. The material can therefore be produced in a relatively cost-effective manner.

Moreover, the invention provides a thermoelectric element composed of the above-described material. For example, the thermoelectric element is used as a generator.

For example, two conductors comprising different materials can be electrically connected to one another in the thermoelectric element. In particular, one conductor may comprise a material of the n-type and the other conductor a material of the p-type. The doped calcium manganese oxide described here is preferably used as the material of the n-type. For example, the materials can be configured as rod- or disk-shaped components.

In an embodiment, the thermoelectric element additionally comprises a material of the p-type. Sodium cobaltate is particularly suitable for this purpose. For example, the material is based on a composition represented by the formula (Ca₃₋ₓNaₓ)Co₄O_{9-δ}, where 0.1≦x≦2.9 and 0<δ≦2, and preferably 0.3≦x≦2.7 and 0<δ≦1 is true. It has been found that such a material shows high thermopower and high conductivity.

In an embodiment, a plurality of thermoelectric elements is interconnected to form a module. At least one thermoelectric element comprises the above-described material based on calcium manganese oxide.

The material in preferably mass-produced in a simple manner using the methods of technical ceramics. In particular, there is no need for cost-intensive processes such as spark plasma sintering or firing in special gas mixtures such as Ar/H₂.

According to a further aspect of the present invention, a method for producing a material for a thermoelectric element is provided. In particular, the above-described material can be produced by this method. All of the properties disclosed with respect to the material are also correspondingly disclosed with respect to the method, and vice versa, even if the respective property is not expressly mentioned in the context of the respective aspect. However, the method can also be used for producing another material for a thermoelectric element. In particular, this can be a material based on calcium manganese oxide that is not doped with Fe atoms.

The method comprises a firing process, wherein the maximum temperature in the firing process is just above the melting point of the material. For example, the maximum temperature Tₘₐₓ is ≧T_{S}−75° C., where T_{S} denotes the melting temperature of the material. The maximum temperature should be selected in such a way that no melting of the material occurs. The maximum temperature should preferably be at least 10° C. below the melting temperature.

The high firing temperature allows favorable growth of polycrystals to be achieved. In particular, the high firing temperature makes it possible to reduce the number of grain boundaries per unit length. In this manner, a material having high electrical conductivity can be produced.

In an embodiment, the temperature is maintained in the aforementioned range for several hours, for example, at least 10 hours.

Moreover, sintering is provided in an atmosphere containing sufficient oxygen. For example, sintering is provided in an air atmosphere or an oxygen-enriched atmosphere.

Moreover, the method is also characterized by a slow cooling rate. In particular, a cooling rate is used of less than or equal to 2° C./min, and preferably less than or equal to 1° C./min. Such a cooling rate is used in particular in cooling from 1000° C. to 600° C. The slow cooling rate protects the material as it goes through phase transitions and therefore makes it possible to produce a ceramic with few or no cracks.

In cooling, moreover, preferably in the range of 1000° C. auf 600° C., it is advantageous to have a maintenance time of at least 30 minutes, and preferably at least one hour. For example, the temperature during the maintenance time is in the range of 700° C. to 800° C. e.g., 750° C. This additional maintenance time allows re-oxidation of Mn³⁺ to Mn⁴⁺ to be carried out as completely as possible and improves thermoelectric properties such as thermopower and electrical conductivity.

### BRIEF DESCRIPTION OF THE DRAWINGS

In the following, the subject matter described here is explained in further detail based on working examples depicted schematically and not to scale.

The figures show the following:

FIG. 1 is a diffractogram of a material for a thermoelectric element,

FIG. 2 is a diagram of electrical conductivity as a function of maximum firing temperature for two materials,

FIG. 3 is a micrograph of a material,

FIG. 4 is a diagram of electrical conductivity as a function of temperature for a material,

FIG. 5 is a diagram of the Seebeck coefficient as a function of temperature for the material of FIG. 4,

FIG. 6 is a diagram of thermal conductivity as a function of temperature for the material of FIG. 4,

FIG. 7 is a diagram of figure of merit as a function of temperature for the material of FIG. 4,

FIG. 8 is a diagram of thermal conductivity as a function of temperature for two further materials,

FIG. 9 is a diffractogram of two materials,

FIG. 10 is a diagram of sintering density as a function of Fe content in a material,

FIG. 11 is a diagram of the Seebeck coefficient as a function of Fe content in the material of FIG. 10,

FIG. 12 is a diagram of sintering density as a function of Fe content in two materials,

FIG. 13 is a diagram of the Seebeck coefficient as a function of Fe content in the two materials of FIG. 12, and

FIG. 14 is a working example of a thermoelectric generator having a plurality of thermoelectric elements.

### DETAILED DESCRIPTION OF ILLUSTRATIVE EMBODIMENTS

### Method for Producing the Material

### Example: Preparation of Ca_{0.85}Sr_{0.10}Dy_{0.05}Mn_{0.975}Fe_{0.025}O₃

A method is first described for producing a material for a thermoelectric element.

For example, the method is used to produce a material of the composition Ca_{0.85}Sr_{0.10}Dy_{0.05}Mn_{0.975}Fe_{0.025}O₃. However, the method is not limited to this material, but is also suitable for producing other materials for thermoelectric elements.

For example, the material, preferably a complex metal oxide, can be produced by means of the so-called “mixed oxide” process. However, it is also possible to use other production methods, such as wet-chemical routes or mechanical alloying.

Stoichiometric amounts of CaCO₃, SrCO₃, Mn₃O₄, Fe₂O₃, and Dy₂O₃ are weighed in and wet-ground (using deionized water). A microfine grain size is achieved using suitable fine milling technology such as a planetary mill or an agitator bead mill. The grain size distribution is preferably d(0.5)<1 μm and d(0.9)<1.5 μm. This makes it possible to achieve sufficient reactivity in the subsequent calcining process. The milled suspension is dried and sifted.

Calcination, in which a solid-state reaction takes place to form a complex metal oxide, is carried out, for example, at 1100° C. in an air atmosphere for several hours. In this reaction, a largely single-phase material is preferably obtained. Small amounts of unreacted raw materials from second phases can further react in subsequent firing to form a complex metal oxide.

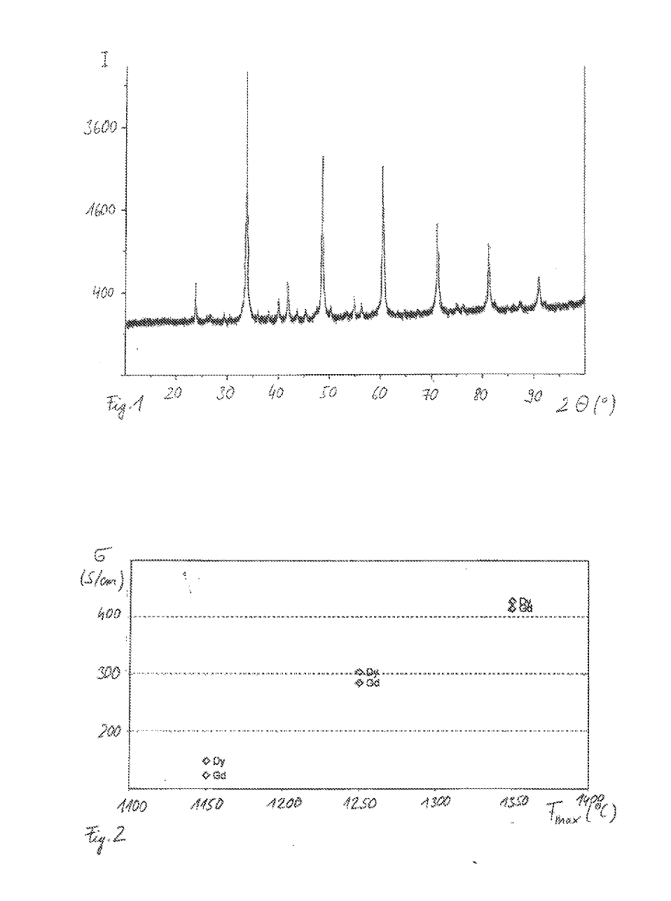

FIG. 1 shows an x-ray diffractogram (XRD) of the working example. The measured radiation intensities I are plotted against the angle of the radiation source, sample, and detector (2θ angle). A comparison with the values reported in the literature for CaMnO₃ shows that incorporation of Fe atoms has taken place without any substantial change in the structure of the ABO₃ unit cell.

In order to provide good sinterability for firing of the components, it is advantageous to repeat the step of micronization. For this purpose, the powder is again mixed with deionized water and finely milled. One should preferably aim for a grain size distribution having roughly the following properties: d(0.5)=0.5 μm and d(0.9)≦1 μm. In the next step, a pressable powder or granulate is produced from the milled suspension. This can be carried out directly by spray-drying of a suspension mixed with a binder, or—in the case of small amounts, for example,—by drying the suspension and then manually adding a binder component.

Shaping of the component is now carried out. Components are preferably molded by means of dry pressing. For the production of conversion modules, for example, rod-shaped or cylindrical components are required. Before subsequent firing of the components, pre-decarbonization is advantageous (using thermal releasing agents). It has been found that firing of the components is of great importance in configuring the thermoelectric properties of the material described.

The measurements of sintering density were carried out on a cylindrical component having a diameter of 11 mm and a height of 5.5 mm. The measurements of electrical conductivity and thermopower were carried out on a cylindrical component having a diameter of 10 mm and a height of 1 mm. The measurements of thermal conductivity were carried out on a cylindrical component having a diameter of 11 mm and a height of 1 mm.

### Optimization of the Firing Process

### Example: Ca_{0.95}Dy_{0.05}MnO₃ and Ca_{0.95}Gd_{0.05}MnO₃

The optimized firing process developed is described below by way of example for the materials Ca_{0.95}Dy_{0.05}MnO₃ and Ca_{0.95}Gd_{0.05}O₃. The method is not limited to these materials, but was successfully used in producing all of the tested formulations of a complex metal oxide.

A particularly high maximum firing temperature is used in the method. However, the maximum firing temperature should be below the melting temperature, as the component could otherwise melt and be destroyed. The firing temperature is preferably just below the melting temperature of the material used.

For example, the maximum firing temperature Tₘₐₓ is 100° C. below the melting temperature T_{S} or above it, i.e., Tₘₐₓ≧T_{S}−100° C. In an embodiment, Tₘₐₓ≧T_{S}−75° C. is true, e.g., Tₘₐₓ≧T_{S}−50° C. The firing temperature is preferably at least 10° C. below the melting temperature, i.e., Tₘₐₓ≦T_{S}−10° C. For example, the firing temperature is in the range of 10° C. to 50° C. below the melting temperature. For the materials tested here, for example, the melting temperature is approx. 1400° C.

In the method, a very long maintenance time at the maximum temperature is preferred. In particular, the maintenance time is at least 10 h. For example, the maintenance time is at least 15 h.

Sintering is preferably carried out in an atmosphere having sufficient oxygen. For example, sintering is carried out in an air atmosphere or an oxygen-enriched atmosphere.

Moreover, the method is characterized by a slow cooling rate. In particular, a cooling rate of less than or equal to 1° C./min is used in cooling from 1000° C. to 600° C.

Furthermore, in cooling from 1000° C. to 600° C., an additional maintenance time of at least one hour is preferably used.

The slow cooling rate and additional maintenance time allow the most complete conversion from Mn³⁺ to Mn⁴⁺, so that the compound obtained is as stoichiometric as possible and has particularly favorable thermoelectric properties. For this purpose, cooling below a specified temperature is required. On the other hand, the rate of diffusion of the required oxygen in the ceramic decreases with falling temperature. There is therefore an optimum temperature for the maintenance time. In sintering in air and at atmospheric pressure, this temperature is in the range of 700° C. to 800° C., e.g., 750° C. Oxygen uptake is accompanied by phase transitions, which can easily cause the brittle ceramic to crack. A slow cooling rate in the range of the phase transition and below makes it possible to produce a ceramic having few or no cracks.

It has been found that by means of this method, it is possible to find a process window within which favorable grain growth with advantageous properties can be achieved without melting of the ceramic. Moreover, it has been found that a material manufactured in this manner is highly resistant to air and oxygen. In particular, the material remains stable in air up to high temperatures (≧800° C.).

The following table shows the electrical conductivity and density of the fired ceramic for the two formulations at various maximum firing temperatures.

| | Max. firing | Electrical | Density of |
|---|---|---|---|
| | temperature | conductivity | ceramic |
| Formulation | (° C.) | (S/cm) | (g/ml) |
| Ca_{0.95}Dy_{0.05}MnO₃ | 1150 | 148 | 4.27 |
| | 1250 | 304 | 4.66 |
| | 1350 | 428 | 4.66 |
| Ca_{0.95}Gd_{0.05}MnO₃ | 1150 | 123 | 4.07 |
| | 1250 | 285 | 4.62 |
| | 1350 | 416 | 4.62 |

As can be seen from the table, at a maximum firing temperature of Tₘₐₓ=1150° C., the electrical conductivity σ of the two formulations is below 150 S/cm. At this firing temperature, the density of the ceramic is γ<4.3 g/ml for the two formulations. When the maximum firing temperature is increased to Tₘₐₓ=1250° C., electrical conductivity increases sharply. The sintering density also increases. On a further increase in the maximum firing temperature to Tₘₐₓ=1350° C., the electrical conductivity of the two formulations increases to a value of σ>400 S/cm. The density of the ceramic is γ>4.6 g/ml.

FIG. 2 shows a graphical representation of electrical conductivity G as a function of maximum firing temperature Tₘₐₓ for the two formulations. The electrical conductivity shows virtually linear dependency on maximum firing temperature.

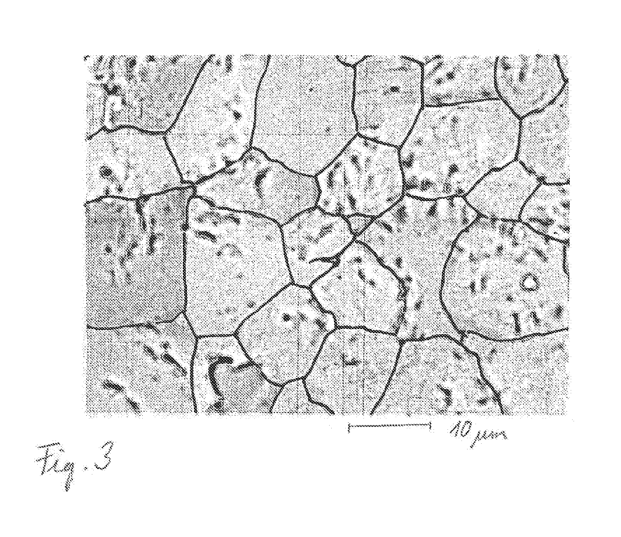

FIG. 3 shows the microgram obtained in sintering as an example for one of the working examples.

By means of the method used, taking a primary grain size of 0.5 μm as a starting point, a stable and dense ceramic composed of grains measuring 10 μm in diameter can be produced. The growth of the grains was therefore greater than one order of magnitude. The favorable electrical conductivity can be attributed to the large grain diameter, as in this case only minor dispersion of the charge carriers takes place at the grain boundaries.

In the following, various materials and components containing the materials are characterized. All of the materials or components were produced by the above-described method. In particular, the components of a complex metal oxide can be determined by comparing their properties.

### Example: Ca_{0.97}La_{0.03}MnO₃

As a first example, a ceramic based on calcium manganese oxide (calcium manganate) is tested in which Ca²⁺ has been partially replaced by a suitable atom with a valence of 3+, corresponding to donor doping in the A position. The ceramic is represented by the formula Ca_{0.97}La_{0.03}MnO₃. Sintering was carried out at a maximum temperature of 1320° C.

The following properties in particular are relevant for thermoelectric conversion. Characterization was conducted at room temperature.

| | |
|---|---|
| Sintering density | γ = 4.61 g/cm³ |
| Electrical conductivity | σ = 258 S/cm |
| Thermopower | α = −125 μV/K |
| Power factor (σ · α²) | PF = 4.06 · 10⁻⁴ W/(mK²) |
| Thermal conductivity | κ = 3.89 W/(mK) |
| Figure of merit | ZT = 0.033 |

For thermoelectric conversion, the dependency of the properties on the surrounding temperature is of particular interest. The ends of a thermoelectric component are at different temperature levels. The amount of energy converted increases with increasing temperature difference, provided that the figure of merit does not decrease disproportionately with temperature.

FIG. 4 shows the temperature dependency of electrical conductivity σ for the Ca_{0.97}La_{0.03}MnO₃ ceramic. The measurements were carried out in two components. The components were produced under the same conditions. The virtually identical measurement results demonstrate the favorable reproducibility of component production and of the measurement method.

Electrical conductivity σ decreases with increasing temperature. This reduction in conductivity with temperature is also referred to as “metallic” behavior.

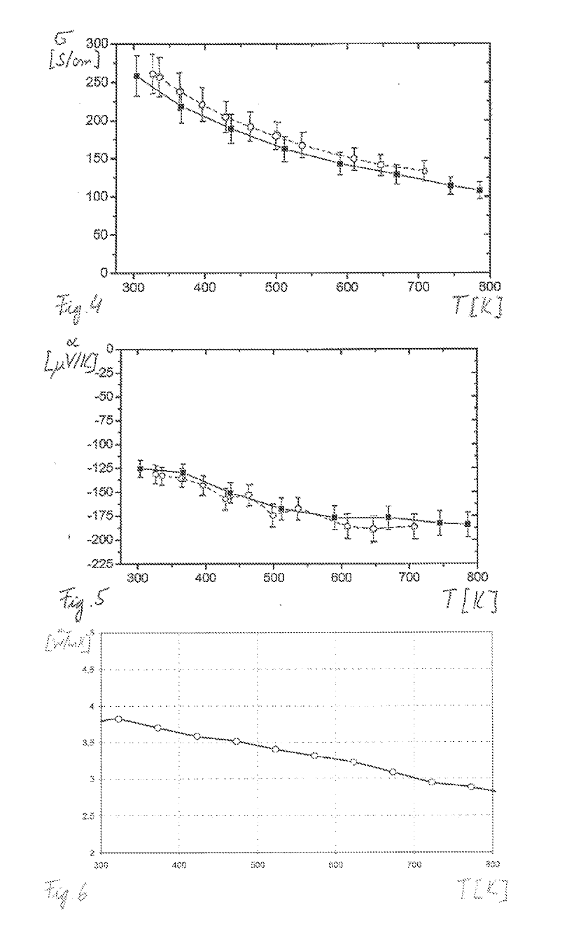

FIG. 5 shows the temperature dependency of the Seebeck coefficient α for the two components. In this case, an increase in the absolute value with increasing temperature can be observed.

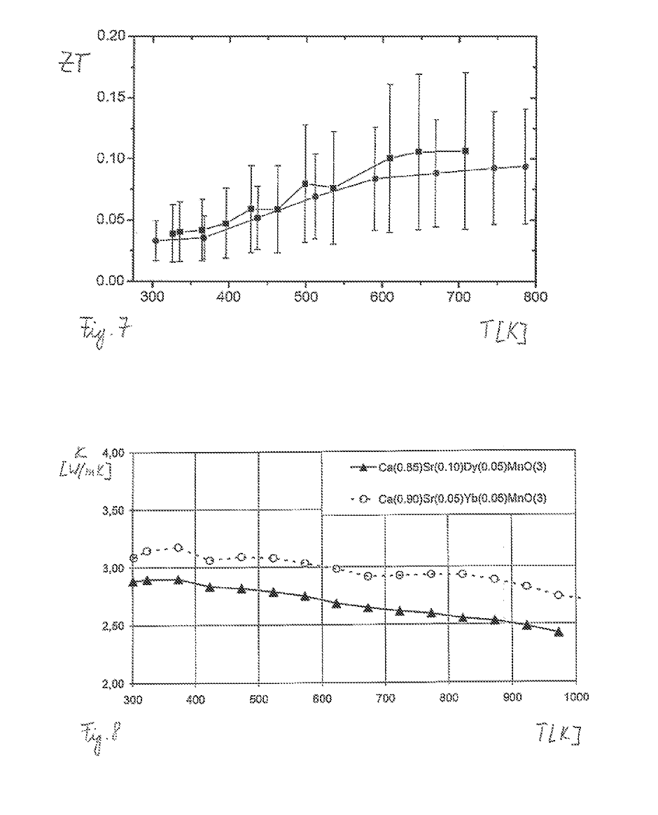

FIG. 6 shows the temperature dependency of thermal conductivity K for one of the components. Thermal conductivity was measured by means of a laser flash method. Thermal conductivity decreases with increasing temperature.

Based on these measurements, the figure of merit ZT can be derived by means of equation (1).

FIG. 7 shows the course of the figure of merit ZT, measured in the two components of the Ca_{0.97}La_{0.03}MnO₃ ceramic. The figure of merit reflects the efficiency of thermoelectric conversion.

### Example: Ca_{0.9}Sr_{0.05}Yb_{0.05}MnO₃

As a further example, a ceramic based on calcium manganate was tested in which donor doping with Yb³⁺ was carried out instead of donor doping with La³⁺. The doping content was also increased from 3% to 5%. In this case, an increase in the number of charge carriers and thus improved electrical conductivity is to be expected. However, the number of charge carriers also affects the result (See, e.g., “Heike's formula”). At a donor content of y>50%, the conduction mechanism usually changes to hole conduction, so the donor content should be less than 50%.

In addition, 5% of the Ca²⁺ atoms were replaced by specific heavier Sr²⁺ atoms. With an unchanged unit cell of the perovskite structure, this should make it possible to increase the density of the material and reduce thermal conductivity.

The material is therefore represented by the formula Ca_{0.9}Sr_{0.05}Yb_{0.05}MnO₃. The above-described method was again used for production.

Characterization of the component at room temperature was again conducted:

| | |
|---|---|
| Sintering density | γ = 4.70 g/cm³ |
| Electrical conductivity | σ = 399 S/cm |
| Thermopower (Seebeck coefficient) | α = −101 μV/K |
| Power factor | PF = 4.05 · 10⁻⁴ W/(mK²) |
| Thermal conductivity | κ = 3.08 W/(mK) |
| Figure of merit | ZT = 0.040 |

It can be derived from these values that the improved electrical conductivity is compensated for by the reduced thermopower, so that the power factor remains approximately the same. An increase in sintering density of approx. 2% and a decrease in thermal conductivity of approx. 20% can be observed, which therefore also improves the figure of merit ZT by approx. 20%.

Overall, it was found that material modifications that specifically lead to denser structures with reduced thermal conductivity constitute an interesting alternative to material changes that only alter the electronic properties of the oxide ceramic.

### Example: Ca_{0.85}Sr_{0.10}Dy_{0.05}MnO₃

As a further example, a ceramic based on calcium manganate was tested in which even more Ca²⁺ atoms (10%) were specifically replaced by heavier Sr²⁺ atoms. The donor doping content was kept at 5%, but doping was carried out in this case with Dy³⁺.

The material is therefore represented by the formula Ca_{0.85}Sr_{0.10}Dy_{0.05}MnO₃. The above-described method was again used for production.

At room temperature, the following properties are seen compared to the preceding examples:

| | | | Thermal |
|---|---|---|---|
| Comparison | | Sintering density | conductivity |
| example | Material | (g/ml) | (W/mK²) |
| 1 | Ca_{0.97}La_{0.03}MnO₃ | 4.61 | 3.89 |
| 2 | Ca_{0.90}Sr_{0.05}MnO₃ | 4.70 | 3.08 |
| 3 | Ca_{0.85}Sr_{0.10}Dy_{0.05}MnO₃ | 4.74 | 2.88 |

The Ca_{0.85}Sr_{0.10}Dy_{0.05}MnO₃ and Ca_{0.9}Sr_{0.05}Yb_{0.05}MnO₃ ceramics thus show increased sintering density and reduced thermal conductivity.

FIG. 8 shows the dependency of temperature on thermal conductivity for the materials

Ca_{0.85}Sr_{0.10}Dy_{0.05}MnO₃ and Ca_{0.9}Sr_{0.05}Yb_{0.05}MnO₃. It can be seen that there is reduced thermal conductivity in the entire range of 300 to 1000 Kelvins.

The three examples show that the efficiency of thermoelectric conversion can be improved by means of structures having increased density and reduced thermal conductivity.

It would be expected that this effect could be further increased by further or complete replacement of Ca²⁺ atoms by specific heavier Sr²⁺ atoms. However, it was found that at a content of over 20% Sr²⁺ atoms, there is an increasing change in the unit cell of the perovskite, which thus alters the electronic properties (conductivity, thermopower) in an unfavorable manner. The changed structure of the unit cell can be seen, for example, on the x-ray diffractogram (XRD).

It has been found that a further increase in efficiency can be achieved by incorporating suitable atoms that are even heavier than Sr²⁺. For example, Ba²⁺ and Pb²⁺ are suitable for this purpose.

### Example: Ca_{0.85}Sr_{0.10}X_{0.05}Mn_{1-z}Fe_{z}O₃(X═Dy, Bi)

As a working example of a material based on CaMnO₃ doped with Fe atoms that replace Mn atoms, a material is characterized below that is represented by the formula Ca_{0.85}Sr_{0.10}X_{0.05}Mn_{1-z}Fe_{z}O₃, where X is equal to Dy or Bi. A portion of the Mn atoms in the B positions is therefore replaced by Fe atoms. The vast majority (>80%) of the B positions are occupied by Mn atoms. For this reason, the crystal structure and stability of the manganate compound that are beneficial for thermoelectric conversion are largely retained.

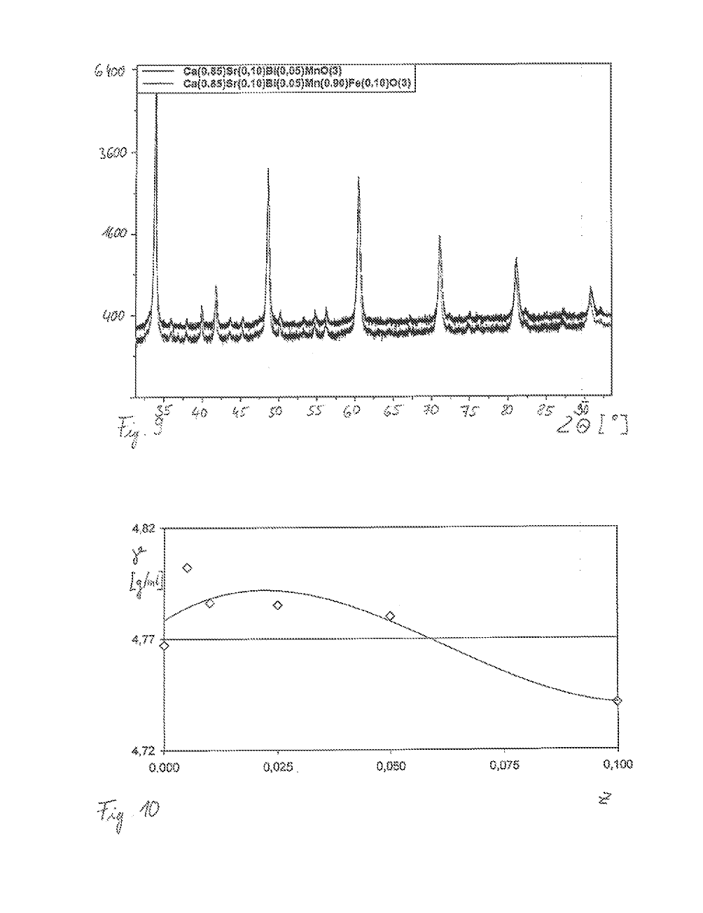

FIG. 9 shows a comparison of the x-ray diffractograms for the compounds

Ca_{0.85}Sr_{0.10}Bi_{0.05}MnO₃ and Ca_{0.85}Sr_{0.10}Bi_{0.05}Mn_{0.90}Fe_{0.10}O₃.

A virtually identical reflex pattern can be seen, although 10% of the Mn atoms in the B position are replaced by Fe atoms. This means that incorporation of the Fe atoms took place without any substantial change in the structure of the ABO₃ unit cell.

In the following, the effect of the content of incorporated Fe atoms is investigated in further detail. In particular, the content z of Fe atoms in the material of formula Ca_{0.85}Sr_{0.10}Dy_{0.05}Mn_{1-z}Fe_{z}O₃ is varied.

FIG. 10 shows the dependency of sintering density on the content z of Fe atoms in this material. Fe contents of z=o %, 0.5%, 1%, 2.5%, 5% and 10% were tested. The compensation curve was roughly estimated.

It can be seen from FIG. 10 that with an added amount of up to 5% Fe, density is higher than the value for the Fe-free compound. At 10% or above, density again decreases sharply. Because of the increased density at up to 5% Fe, and because the Fe atoms in the lattice are to be seen as defects for phonons, it can be concluded that the thermal conductivity in this range is also below the value for the Fe-free compound.

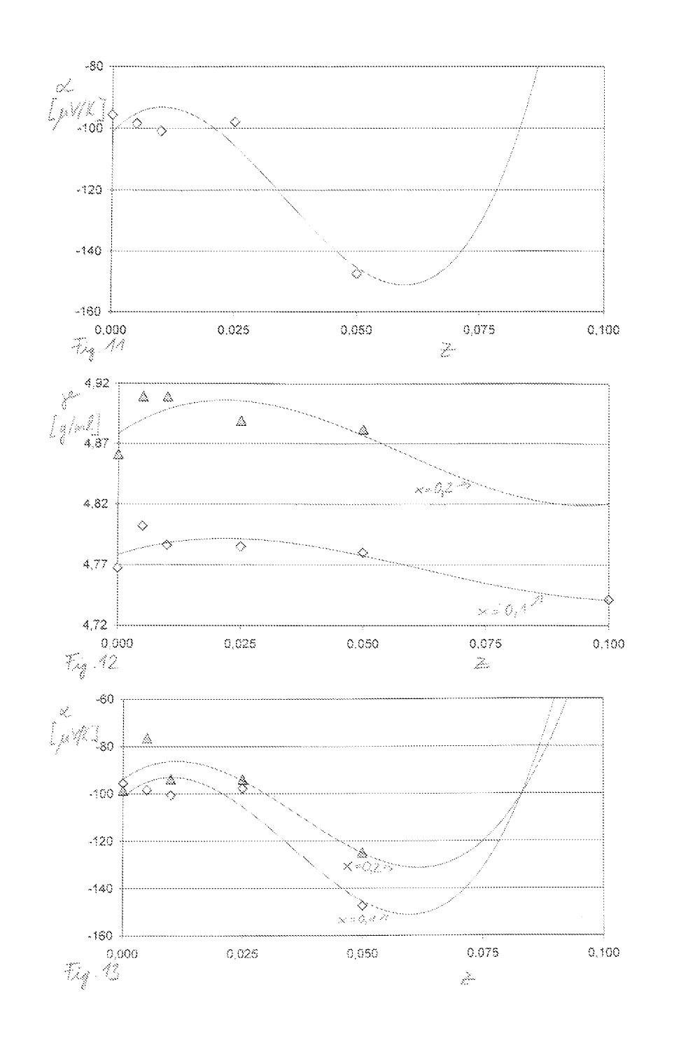

FIG. 11 shows the dependency of the Seebeck coefficient α on the Fe content z of this material. Measurements were conducted at room temperature. Fe contents of z=0%, 0.5%, 1%, 2.5%, 5% and 10% were again tested. The compensation curve was roughly estimated.

Up to approx. 10% Fe content, thermopower is negative (the material is of the “n-type”). Up to 5%, the absolute value of the Seebeck coefficient increases. With addition of slightly more than 5% Fe, thermopower again decreases sharply.

The parameters of thermoelectric conversion can therefore be optimized by means of the measurement values from FIGS. 10 and 11. It has been found that a material having an Fe content in the range of 0.0001 to 0.2 shows advantageous properties. At an Fe content of z>0.2, electronic conductivity is extremely low.

### Example: Ca_{1-x-0.05}SrₓDy_{0.05}Mn_{1-z}Fe_{z}O₃

As a further working example, a material is characterized in which the Sr content is increased from 10% to 20% compared to the preceding working example. In particular, a material of the formula Ca_{1-x-0.05}SrₓDy_{0.05}Mn_{1-z}Fe_{z}O₃ is characterized. Again, a variation of the content z of Fe atoms is tested.

FIG. 12 shows the dependency of sintering density γ on Fe content z for Sr content of x=10% and x=20%.

The incorporation of a greater number of “heavier” Sr atoms increases the density of the ceramic produced and reduces its thermal conductivity. However, it has been found that with an Sr content of x>50%, the properties strongly resemble the more unfavorable properties of SrMnO₃.

Even with an Sr content of 20%, an additional positive effect on sintering density is seen with Fe addition of up to 5%.

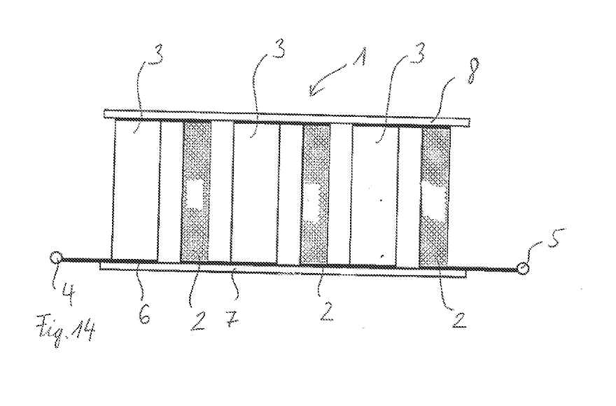

FIG. 13 shows the dependency of thermopower a on Fe content z for an Sr content of x=10% and x=20%.

The resulting course is similar to that shown in the working example of FIG. 11. Up to a content of approx. 10% of added Fe, the thermopower is negative (the material is of the “n-type”). Up to approx. 5% Fe content, the absolute value of thermopower increases in an advantageous manner.

FIG. 14 shows a working example of a thermoelectric element 1, in particular a thermoelectric generator.

The generator has a so-called H structure. The generator is configured as a module having a plurality of materials 2, 3 of different types. The materials 2, 3 form the legs of the generator. The first material 2 is of the n-type, and as described above, is based on calcium manganese oxide. The second material 3 is of the p-type. The two materials 2, 3 preferably have comparable figures of merit. In this case, particularly favorable energy conversion can be achieved overall.

For example, a sodium cobaltate based on the general formula (Ca₃₋ₓNaₓ)Co₄O_{9-δ}, where 0.1≦x≦2.9 and 0<δ≦2, and particularly where 0.3≦x≦2.7 and 0<δ≦1, is used for the second material 3.

The legs comprising the materials 2, 3 are thermally parallel and electrically connected in series. Contacts 6 composed, e.g., of an Ag paste are provided for electrical connection purposes.

The generator has two electrical connections 4, 5. Thermal contact elements 7, 8 are also present that simultaneously form electrical insulators. Examples of compounds used for this purpose include Al₂O₃, AlN and/or Si₃N₄. For example, the materials 2, 3 are sintered together with the electrical contacts 6 and the thermal contact elements 7, 8.

When there is a temperature difference between the two contact elements 7, 8, a voltage referred to as thermopower is generated between the electrical connections 4, 5.

In an alternative embodiment, a thermoelectric element, in particular a thermoelectric generator, has only two legs composed of different materials 2, 3.

1-15. (canceled)

16. A thermoelectric element comprising:
a material comprising calcium manganese oxide that is partially doped with Fe atoms in positions of Mn atoms.

17. The thermoelectric element according to claim 16, wherein a doping with Fe atoms provides a content of z≦20% at the positions of Mn atoms.

18. The thermoelectric element according to claim 16, wherein the material is further doped with an element that provides electrons for electrical conductivity in positions of Ca²⁺ atoms.

19. The thermoelectric element according to claim 18, wherein the element is selected from the group consisting of rare earth metals, Sb³⁺, and Bi³⁺.

20. The thermoelectric element according to claim 18, wherein a doping with the element provides a content of 0<y≦0.5 at the positions of Ca atoms.

21. The thermoelectric element according to claim 16, wherein the material is further doped with a divalent element in positions of Ca²⁺ atoms.

22. The thermoelectric element according to claim 21, wherein the divalent element is selected from a group consisting of Mg²⁺, Sr²⁺, Ba²⁺, Zn²⁺, Pb²⁺, Cd²⁺ and Hg²⁺.

23. The thermoelectric element according to claim 21, wherein a doping with the divalent element provides a content of 0<x≦0.5 at the positions of Ca atoms.

24. The thermoelectric element according to claim 23, wherein the doping with the divalent element provides a content of x≧0.05.

25. The thermoelectric element according to claim 16, wherein the material is represented by the general formula Ca_{1-x-y}ISOₓDON_{y}Mn_{1-z}Fe_{z}Oₙ, wherein ISO denotes a divalent element that can replace Ca²⁺ in a crystal lattice, wherein DON denotes an element that can replace Ca²⁺ in the crystal lattice and provides electrons for electrical conductivity, and wherein 0≦x≦0.5; 0<y≦0.5; 0.0001≦z<0.2; n≧2.

26. The thermoelectric element according to claim 16, further comprising a second material based on the composition (Ca₃₋ₓNaₓ)Co₄O_{9-δ}, wherein 0.1≦x≦2.9 and 0<δ≦2.

27. A method for producing a material for a thermoelectric element, the method comprising: firing a material, wherein, for a maximum temperature Tₘₐₓ, Tₘₐₓ≧T_{S}−75° C. is true, wherein T_{S} denotes a melting temperature of the material, and wherein a maintenance time of at least 30 minutes is observed on cooling at a preset temperature.

28. The method according to claim 27, wherein the temperature during the maintenance time is in a range of 700° C. to 800° C.

29. The method according to claim 27, wherein the maximum temperature is greater than or equal to T_{S}−75° C. for at least 10 hours.

30. The method according to claim 27, wherein a cooling rate of less than or equal to 1° C./min is used in cooling.
